(19) United States
(12) Patent Application Publication
(10) Pub. No.: US 2008/0079043 A1
(43) Pub. Date: Apr. 3, 2008

(54) LIGHT SENSING PIXEL OF IMAGE SENSOR WITH LOW OPERATING VOLTAGE

(76) Inventors: Mi Jin KIM, Daejeon (KR); Bong Ki MHEEN, Daejeon (KR); Young Joo SONG, Daejeon (KR)

Correspondence Address: LADAS & PARRY LLP, 224 SOUTH MICHIGAN AVENUE, SUITE 1600, CHICAGO, IL, 60604, US

(21) Appl. No.: 11/857,001

(22) Filed: Sep. 18, 2007

(30) Foreign Application Priority Data
Sep. 29, 2006 (KR) 10-2006-0096333

(51) Int. Cl. H01L 27/146

(52) U.S. Cl. 257/292; 257/E27.133

(57) ABSTRACT

Provided is a light sensing pixel including an image sensor. In a general four-transistor Complementary Metal-Oxide Semiconductor (CMOS) image sensor, unlike a conventional structure, a transfer transistor in a pixel includes a depletion region separated from a channel that is not influenced by a turn-on voltage of the transfer transistor regardless of a driving voltage or a driving method when a photodiode is reset and transferred. As a result, dark current or fixed pattern noise, caused by a change in operating condition of the transfer transistor and inconsistent characteristics between the pixels, is reduced.

The image sensor includes a light sensing pixel that includes the transfer transistor for transferring a light-induced charge generated by the photodiode. The light sensing pixel, to dispose the depletion region between the channel of the transfer transistor and a diffusion node, i.e., to operate in the similar pinch-off state, may have a structure in which an insulating layer of the diffusion node side is thicker than a gate insulating layer adjacent to the photodiode in the transfer transistor. That is, the insulating layer of the transfer transistor has steps or a gradual change in thickness. Also, the light sensing pixel may have a structure in which pocket/halo implant using electrically the same material as a doping material of a substrate is performed between the channel of the transfer transistor and the diffusion node.

### CROSS-REFERENCE TO RELATED APPLICATION

This application claims priority to and the benefit of Korean Patent Application No. 2006-0096333, filed Sep. 29, 2006, the disclosure of which is incorporated herein by reference in its entirety.

### BACKGROUND

1. Field of the Invention

The present invention relates to a light sensing pixel including an image sensor, a transfer transistor for transferring a light-induced charge implemented in the image sensor, and a photodiode. More particularly, the present invention relates to a light sensing pixel of an image sensor maintaining depletion of charge in a photodiode at the same level when the photodiode is reset and light-induced charge accumulated in the photodiode is transferred, and reducing clock-feed-through of channel charge according to on/off of a reset transistor.

This work was supported by the IT R&D program of Ministry of Information and Communication/Institute for Information Technology Advancement [2005-S-017-02, Integrated Development of Ultra Low Power RF/HW/SW SoC.]

2. Discussion of Related Art

Image sensors are largely classified as Charge-Coupled Device (CCD) sensors and Complementary Metal-Oxide Semiconductor (CMOS) sensors. Basically, the two sensors use electron-hole pairs generated by light having a greater energy than a band gap of silicon, and they generally estimate an amount of irradiated light by collecting electrons or holes.

The CMOS image sensor is implemented with a photodiode and a transistor in each image sensor, similar to a general CMOS device, and thus uses a conventional method of manufacturing the CMOS semiconductor. Therefore, compared with the CCD that must have an image signal processor in a separate chip, the CMOS may integrate circuits for processing and detecting an image signal in an external block of a pixel. Additionally, the CURIOS can operate at a low voltage and can be produced at low cost.

The conventionally used CMOS image sensor is classified into a four-transistor pixel structure and a three-transistor pixel structure depending on the number of transistors that constitute one pixel. In spite of the advantages of the three-transistor pixel structure in view of fill factor and manufacturing cost, the four-transistor pixel structure is generally used. This is because a light receiver is separated from a detector, and the light receiver is made of silicon bulk except for a surface, so that the four-transistor pixel structure has high responsiveness and sensitivity with respect to light and has low dark current and noise.

The general four-transistor pixel structure is illustrated in FIG. 1. The four-transistor pixel structure includes four transistors, and a photodiode PD that is light sensing means and four N-channel Metal-Oxide Semiconductors (NMOS) transistors constitute a unit light sensing pixel. A transfer transistor Tx of the four NMOS transistors transfers a photocharge generated from the photodiode PD to a diffusion node 131. A reset transistor Rx outputs a charge stored in the diffusion node 131 or the photodiode PD to detect a signal. Also, a drive transistor Dx acts as a source follower transistor and a switch transistor Sx is for switching/addressing.

The transfer transistor Tx may be implemented with a gate electrode material, a gate insulating layer, and a p-type substrate. Further, the photodiode PD may be implemented with an n− or an n0 doping region and a surface p-type doping region. Additionally, the diffusion node 131 may be implemented with an n+ doping region.

The photodiode PD and a capacitance 118 parallel to the photodiode PD constitute the light receiver, and the transfer transistor Tx transferring the received electron transfers electrons generated by a photon to the diffusion node 131. To obtain a two-dimensional image, a potential is applied through a gate 141 of the switch transistor Sx, thereby selecting a row and a column. Particularly, each pixel is biased by a current source 150, and the current source 150 drives the drive transistor Dx and switch transistor Sx so that the potential of the diffusion node 131 may be read at an output node 142.

The illustrated four-transistor pixel CMOS image sensor transfers the light-induced charge accumulated in the photodiode to a floating diffusion node, after the photodiode is reset, so that the amount of light-induced charge is detected through a voltage drop of the diffusion node.

At this time, to precisely and regularly detect the amount of accumulated light-induced charge, the transfer transistor should be constantly and regularly reset and transferred. In the conventional four-transistor pixel, various structures used to constantly reset and transfer the transfer transistor, e.g., a fully reset-type pinned photodiode, etc., are disclosed. The fully reset-type pinned photodiode refers to a diode in a state in which every mobile charge in the photodiode is fully depleted, so that the potential is not changed further when the photodiode is reset.

In this case, ideally, the potential of the photodiode is pinned to a constant value regardless of an external bias environment such as the potential of the floating diffusion node, etc. Because of this, conditions for reset and transfer, according to the operation of the transfer transistor are maintained at the same level, and the conditions for the reset and transfer become the same.

However, according to a reduction in scaling of current semiconductor process and device and operating voltage, the potential of the diffusion node is getting lower. When the fully reset-type pinned photodiode structure is used due to the reduction in the potential of the diffusion node, the pinning potential of the pinned photodiode is lowered as well. The lowered pinning potential may yield deteriorated pixel characteristics such as well capacity and responsiveness of a photodiode with respect to light, and higher fixed pattern noise. Therefore, there is a limit to the reduction in the pinning potential even though the operating voltage is reduced.

Under a general pixel driving condition where a voltage potential (Vdd) is the same as a turn-on potential of a transistor, reset and transfer conditions of the photodiode vary. When the reset transistor is turned on for the reset of the photodiode, the voltage of the diffusion node is fixed to difference (Vdd−Vth) of the voltage potential (Vdd) and a breakdown voltage (Vth) of the reset transistor. A doping concentration of a channel formation portion of the reset transistor is similar to that of a channel formation portion of the transfer transistor. Therefore, when the transfer transistor is turned on, a difference of a gate voltage of the transfer transistor and a voltage of the diffusion node becomes the breakdown voltage, so that the diffusion node is located at a boundary between pinch-off and linear conditions. Accordingly, when the gate voltage of the transfer transistor is applied, electrons may be instantly emitted to a channel of the transfer transistor from the diffusion node. This yields a considerable change in the photodiode reset conditions and furthermore, this change in the reset conditions shows high sensitivity to process variables.

After the photodiode is reset and before the photodiode-generated charge is transferred, the diffusion node is in the floating state. In a power potential, the voltage of the diffusion node is fixed to a voltage obtained by a difference of the breakdown voltage of the reset transistor and a voltage by clock-feed-through according to the turn-off of the reset transistor.

The potential of the diffusion node in the floating state is more linear than in the reset of the photodiode. As the voltage of the transfer transistor is increased according to coupling capacitance between the transfer transistor and the diffusion node, the voltage of the floating diffusion node is increased as well. Additionally, since the diffusion node is floated, instant emission of electrons to the channel of the transfer transistor has an effect on the voltage of the diffusion node again. Therefore, the transfer condition of the photodiode is changed by the method of applying voltage to a transfer gate in addition to the process variables.

In the case of the fully reset-type pinned photodiode, effects brought on by the photodiode reset and transfer conditions may be excluded. However, even though the pinning potential of the photodiode is lowered at the cost of light responsiveness or well capacity as the operating voltage is reduced, since the reset condition of the photodiode is different from the transfer condition of the photodiode, the pinning potential of the photodiode is inevitably lowered so that the photodiode is pinned to a constant potential. Further, since effects brought on by the process variables or a driving method should be compensated for, it is difficult to determine the pinning voltage and the physical structure of the photodiode.

In addition, a predetermined amount of potential barrier inevitably exists between the pinned photodiode, on which a p-type doping layer for surface pinning is formed, and the channel of the transfer transistor. Therefore, to remove the effects brought on by the barrier caused by the reset or transfer of the photodiode, the pinning potential, the potential of the floating diffusion node, and the turn-on potential of the transfer transistor should be sufficiently different from one another.

If the barrier is not sufficiently reduced, the photodiode is not fully reset even though the pinning voltage of the photodiode is significantly lowered. Further, the amount of charge left in the photodiode when the photodiode is reset and transferred is determined by the barrier, that is, as the operating voltage is reduced, a difference in voltage between the pinning potential and the potential of the floating diffusion node is reduced as well. Insufficient reduction in the barrier results in a high probability of generating low well capacity, insufficient photodiode reset, and high sensitivity to the process variables.

The conventional art to overcome the above problems includes a method in which the potential of the floating diffusion node is artificially increased from a general potential VDD−VTH to VDD using a voltage applied to a (gate of a reset transistor Rx by means of a boosting circuit. In addition, the conventional art includes another method in which a PMOS is used as the reset transistor Rx rather than the conventional NMOS so that the potential of the floating diffusion node is sufficiently and promptly increased to VDD.

However, when the voltage boosting circuit is used, the reliability of gate oxides may be an issue because a potential equal to or higher than a general operating condition is applied. Also, when the PMOS is used as the reset transistor Rx, since the PMOS occupies a larger space than the NMOS, the characteristics deteriorate due to a reduction in fill-factor and additionally, in view of noise characteristics, it is known that noise is twice as high as that of NMOS operations. Further, these methods may improve efficiency at the same operating voltage rather than act as a solution to overcome the limitation (generated at the low operating voltage, therefore, these methods are not fundamental solutions.

### SUMMARY OF THE INVENTION

The present invention is directed to a light sensing pixel of an image sensor capable of efficiently reducing noise components such as dark current or fixed pattern noise while reducing dependence on the state of a photodiode and a diffusion node, and a driving potential or a driving method of a pixel at a low operating voltage.

For this purpose, even though the photodiode is not fully reset to a pinning potential, almost the same reset and transfer as those of a fully reset photodiode may be accomplished in the present invention. Also, in the present invention, any effects on the reset and transfer of the photodiode caused by a change in turn-on potential of the transfer transistor and potential of the diffusion node during the reset and transfer may be removed. In addition, when a fully reset-type photodiode that is fully reset to the pinning potential is designed, the characteristics of the photodiode may be also improved, and since the effects caused by process variables may be efficiently removed, this structure may be used for the same purpose.

The present invention is also directed to a light sensing pixel in which a channel of a transfer transistor and a diffusion node in an image sensor are separated by a depletion region. This structure may efficiently prevent changes according to a driving voltage of a potential barrier between a photodiode and the channel of the transfer transistor and a voltage of the diffusion node.

A first aspect of the present invention provides a light sensing pixel in which a channel of a transfer transistor and a diffusion node are separated by a depletion region in order to maintain reset and transfer at the same level regardless of an operating voltage, a driving method, and a state of a diffusion node when a photodiode is reset and transferred.

A second aspect of the present invention provides a light sensing pixel capable of efficiently reducing a change in a potential barrier between a channel of a transfer transistor and a photodiode according to overall or partial depletion of the channel region of the transfer transistor and a change in a voltage of a diffusion node when the photodiode is reset and/or transferred.

The aspects of the present invention may be applied to a light sensing pixel including a photodiode collecting light-induced charge generated by light, and a transfer transistor for transferring the collected charge to a diffusion node.

According to the first aspect of the present invention, to implement a structure including the depletion region between the channel of the transfer transistor and the diffusion node regardless of a turn-on voltage of the transistor, the thickness of a gate insulating layer of the transistor is partially adjusted. Also, when a doping material of a substrate between the channel of the transfer transistor and the diffusion node is p-type, such as B or Ga, ion implantation of p-type impurities (pocket/halo implants) having the same electrical characteristics as the doping material of the substrate is performed. In addition, to efficiently prevent or reduce a voltage applied to the transistor from being transferred to the diffusion node, (or to reduce the voltage applied to the transistor from being transferred to the diffusion node), the channel of the transistor may be physically separated from the diffusion node or a drain, or alternatively, a work function of a gate electrode material may be partially adjusted.

Further, the two or more methods may be combined so that a breakdown voltage of the diffusion node side can be higher than a voltage obtained by subtraction of an operating gate voltage of the transfer transistor from the voltage of the diffusion node.

According to the second aspect of the present invention, to prevent the potential barrier between the channel of the transfer transistor and the photodiode from being changed by the operating voltage of the transfer transistor and the potential of the diffusion node during the reset and transfer, the following structures may be provided. When a doping material of a substrate is p-type, such as B or Ga, a doping layer according to implantation of p-type impurities having the same electrical characteristics as the doping material of the substrate may be formed at a side of the photodiode adjacent to the channel of the transfer transistor. Also, the doping layer parallel to a surface of the channel of the transfer transistor and separated from the channel by a predetermined depth may be formed.

When the photodiode is reset or transferred, the amount of charge left in the photodiode after the reset and the amount of charge left in the photodiode after the transfer are influenced by the turn-on voltage of the transfer transistor, a state of the channel of the transfer transistor, and the voltage of the diffusion node.

According to the first aspect of the present invention, when the depletion region is formed between the channel of the transfer transistor and the diffusion node, this may prevent the charge in the diffusion node from being instantly emitted to the channel of the transfer transistor when the photodiode is reset and transferred. Therefore, in the case of the reset or transfer, since the channel is constantly going from full depletion to partial depletion or is in an equilibrium state, the effects brought on by the diffusion node may be efficiently removed when the photodiode is reset and transferred, so that the constant reset and transfer may be accomplished.

Also, the potential barrier between the photodiode and the channel of the transfer transistor is changed by the turn-on voltage of the transfer transistor and a method of applying the voltage, the magnitude of coupling capacity between the transfer transistor and the diffusion node, the amount of equilibrium channel charge when the transfer transistor is turned on, the amount of charge corresponding to well capacity of a photodiode, the amount of charge emitted from the diffusion node to the channel of the transfer transistor, etc., in the process of performing the reset or transfer. This change in the potential barrier yields irregular reset and transfer of the photodiode and a difference in the state of the photodiode after the reset and the transfer.

According to the second aspect of the present invention, this change in the potential barrier may be prevented by forming a layer doped with the same impurities as the substrate formed at the side of the photodiode or formed parallel to the channel surface of the transfer transistor and separated from the channel by a predetermined depth.

Unlike the conventional art in which the photodiode is fully depleted, the present invention mainly focuses on maintaining the amount of charge left in the photodiode after the reset of the photodiode and the amount of charge left in the photodiode after the transfer at the same level by process and structure regardless of process variables, operating voltages, a method of applying voltage, etc. Also, the present invention focuses on minimizing voltage drop according to reset noise and clock-feed-through when the diffusion node is reset. However, even in the case when the photodiode is if Lilly depleted the characteristics may be improved, the effects brought on by the process variables may be efficiently removed, the pinning voltage of the photodiode may be increased at a constant operating voltage and higher well capacity may be obtained to thereby be used for the same purpose.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 is a circuit diagram illustrating a configuration of a general foul-transistor Complementary Metal-Oxide Semiconductor (CMOS) image sensor;

FIGS. 2a and 2b are cross-sectional views of photodiode and transfer transistor regions of a light sensing pixel having a depletion-induced doping region according to an exemplary embodiment of the present invention;

FIGS. 3a to 3e are cross-sectional views of photodiode and transfer transistor regions of a light sensing pixel having a depletion region or a gap region in a channel according to another exemplary embodiment of the present invention; and

FIGS. 4a and 4b are cross-sectional views of photodiode and transfer transistor regions of a light sensing pixel having a potential adjustment doping region according to yet another exemplary embodiment of the present invention.

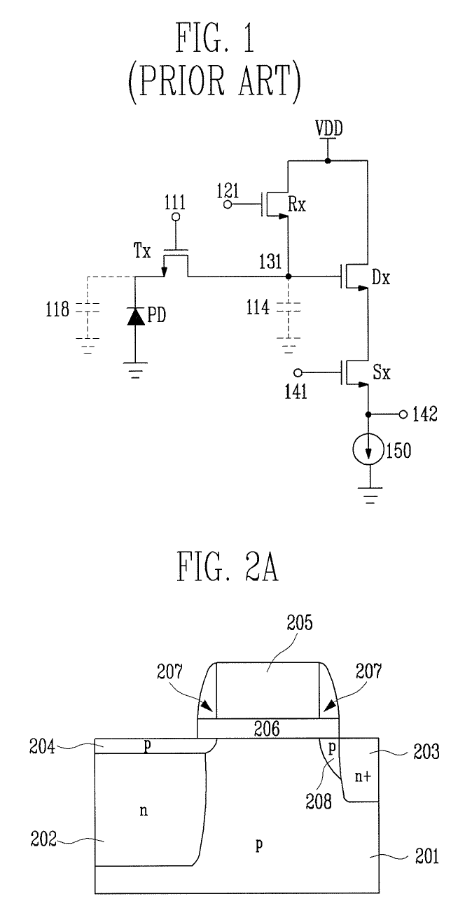

### DETAILED DESCRIPTION OF EXEMPLARY EMBODIMENTS

Hereinafter, exemplary embodiments of the present invention will be described in detail. However, the present invention is not limited to the embodiments disclosed below, but can be implemented in various forms. Therefore, the following embodiments are described in order for this disclosure to be complete and enabling to those of ordinary skill in the art.

For example, while the light sensing pixel of the present invention is applied to a four-transistor CMOS image sensor in the following embodiments, the present invention may be applied to other image sensor Structures including transistors for transferring the photodiode and the light-induced charge generated by the photodiode such as a sense circuit of a low power output terminal in the CCD, and this is within the scope of the present invention.

For example, while the substrate and the surface doping region are doped with p-type, and the diffusion node and the photodiode are doped with n-type in the present exemplary embodiments, it is also possible to dope the substrate and the surface doping region with p-type and to dope the diffusion node and the photodiode with n-type.

### First Exemplary Embodiment

In the present exemplary embodiment, a pixel has a structure in which a channel formation region of a transfer transistor and a diffusion node region are always separated by a depletion region regardless of the magnitude of an operating voltage applied to the transfer transistor and transistors in other pixels, a method of applying a voltage, and a voltage of the diffusion node when a photodiode is reset and light-induced accumulation charge is transferred.

In other words, in the present embodiment, impurity ions are implanted between the diffusion node and the channel of the transfer transistor, regardless of type and thickness of a gate insulating layer of the transfer transistor, so that a potential barrier between the channel region of the transfer transistor and the diffusion node is adjusted. As a result, this structure prevents electrons from being emitted from the diffusion region when the transfer transistor is turned on.

More specifically, when a turn-on voltage is applied to the transfer transistor during the reset and transfer of the photodiode, the channel of the transfer transistor is divided into a diffusion node and a depletion region. As a result, under a constant deep depletion condition, charge in the photodiode is emitted to the channel. According to the amount of electrons emitted from the photodiode to the channel, the charge of the channel is transferred in the direction of the diffusion node so that the channel maintains the equilibrium channel charge or holds the charge under an insignificant deep depletion condition.

Afterwards, as a turn-off voltage is applied to the transfer transistor, most of the charges existing in the channel of the transfer transistor are transferred to the diffusion node by an increase in potential barrier between the photodiode and the channel of the transfer transistor, and a depletion region formed between the diffusion node and the channel of the transfer transistor, i.e., enhanced lateral electric field.

This structure in which the channel of the transfer transistor is separated from the diffusion node by the depletion region is not sensitive to process variables. Also, this structure is capable of constant reset and transfer regardless of a change in the gate turn-on voltage of the transfer transistor, a change in the voltage of the diffusion node, a method of applying a voltage, etc. In this structure, a smaller amount of charge is left in the photodiode when the photodiode is reset or transferred, and the charge of the channel of the transfer transistor does not return to the photodiode. As a result, image lag, fixed pattern noise, and dark current are reduced, and well-capacity is increased.

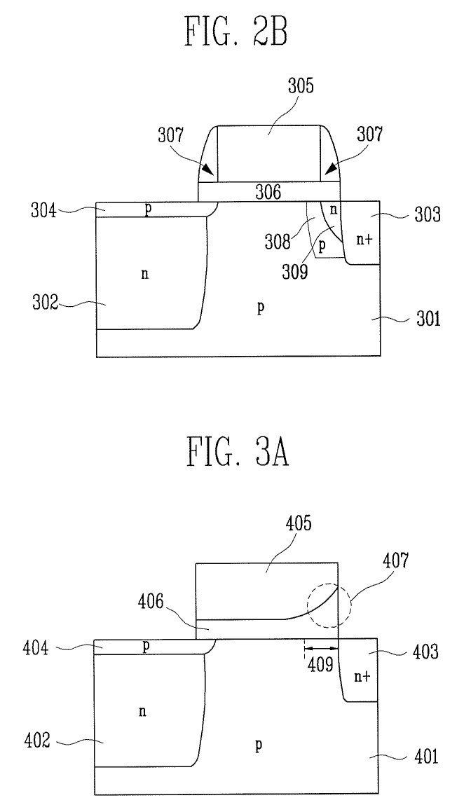

In light sensing pixels of FIGS. 2a and 2b, a p-type doping region is formed between a channel and a diffusion node so that a breakdown voltage of the diffusion node of the transfer transistor is higher than a voltage obtained by subtraction of a gate turn-on voltage of the transfer transistor from a voltage of the diffusion node.

FIG. 2a illustrates an exemplary embodiment of a photodiode region of a four-transistor CMOS image sensor, a transfer transistor, and a diffusion node 203 implemented according to the above aspects. The transfer transistor includes a gate electrode 205, a gate insulating layer 206, a spacer 207, and a substrate 201. The photodiode region includes a photodiode doping region 202 and a surface doping region 204. As a characterized structure of the present invention, a depletion-induced doping portion 208 separates the channel of the transfer transistor from the diffusion node 203 by the depletion region. For this purpose, after the gate insulating layer 206 is formed and the gate electrode 205 is defined, ion implantation of p-type impurities that are the same as a doping material of a substrate is performed at the step of ion implantation for source and drain extension performed between the gate electrode 205 and the diffusion node 203 to thereby form the depletion-induced doping portion 208. Then, the spacer 207 is formed and the diffusion node 203 is formed using n-type impurities.

Specifically, after the gate insulating layer of the transfer transistor and a gate electrode material are formed and defined, when the doping material of the substrate is p-type such as B or Ga, ion implantation of the p-type impurities having the same electrical characteristics as the doping material of the substrate is performed in the shape of pocket/halo at the step of ion implantation for source and drain extension performed between the gate electrode and the diffusion node, and then the diffusion node is formed using n-type impurities such as P or As.

At this time, the depletion-induced doping region 208 may have a minimum doping concentration at which a breakdown voltage of the diffusion node side of the transfer transistor is higher than the voltage obtained by subtraction of the turn-on gate voltage of the transfer transistor from the voltage of the diffusion node. In other words, in a typical Metal-Oxide Semiconductor (MOS) structure, when it is assumed that the transfer transistor gate is a general gate and the diffusion node 203 is a source, the doping concentration does not exceed the breakdown voltage so that electrons are not transferred to the gate channel.

While a light sensing pixel of FIG. 2b is similar to that of FIG. 2a, after a gate insulating layer 306 is formed and a gate electrode 305 is defined, ion implantation of p-type impurities that are the same as a doping material of substrate is performed at the step of ion implantation for source and drain extension performed between the gate electrode 305 and a diffusion node 303 so that a first depletion-induced doping portion 308 is formed. Then, ion implantation of n-type impurities that are the same as the diffusion node 303 is performed again so that a second depletion-induced doping portion 309 is formed. Then, a spacer 307 is formed, and the diffusion node 303 is formed using n-type impurities.

Specifically, after the gate insulating layer of the transfer transistor and a gate electrode material are formed and defined, when the doping material of the substrate is p-type, such as B or Ga, ion implantation of the p-type impurities having the same electrical characteristics as the doping material of the substrate is performed before ion implantation for source and drain extension is performed between the gate electrode and the diffusion node. Then, after extension ion implantation of the n-type impurities such as P or As is performed, the diffusion node is formed using the n-type impurities such as P or As.

It is apparent that the first depletion-induced doping portion 308 and the second depletion-induced doping portion 309 may be structurally changed according to ion implantation materials, ion implantation energy, ion implantation concentration, ion implantation angles, etc. This structure is characterized in that the diffusion node and the transfer transistor are formed by the typical MOS fabrication method. Also, the step of ion implantation of the p-type impurities that are the same as the substrate is added at the step of ion implantation for source and drain extension.

The first depletion-induced doping portion 308 formed by the added ion implantation acts to form a depletion region between the channel of the transfer transistor- and the diffusion node. Also, the minimum doping concentration may be a doping concentration at which the breakdown voltage of the diffusion node side of the transfer transistor is higher than the voltage obtained by subtraction of the turn-on gate voltage of the transfer transistor from the voltage of the diffusion node. In other words, the minimum doping concentration of the first depletion-induced doping portion 308 is the doping concentration at which the breakdown voltage is higher so that the electrons cannot be transferred to the gate channel when it is assumed that the transistor gate is a general gate and the diffusion node regions 303 and 309 are sources in the typical MOS structure.

### Second Exemplary Embodiment

In another exemplary embodiment, when it is assumed that a gate of a transfer transistor corresponds to a general gate in a typical MOS structure, and a diffusion node corresponds to a source, the thickness of a gate insulating layer and a work function between a substrate and a gate electrode material, which have an effect on a breakdown voltage, are partially adjusted. Also, a depletion region may be formed between the diffusion node region and a channel region of the transfer transistor so that the breakdown voltage of the diffusion node side of the transfer transistor is higher than a voltage obtained by subtraction of an operating gate voltage applied to the transfer transistor from a voltage of the diffusion node.

In other words, in a light sensing pixel of the present exemplary embodiment, a lateral electric field formed by the diffusion node is maintained, but a vertical electric field formed by a gate electrode when the transfer transistor is turned-on is deteriorated, so that the depletion region is formed between the diffusion node and the channel of the transfer transistor.

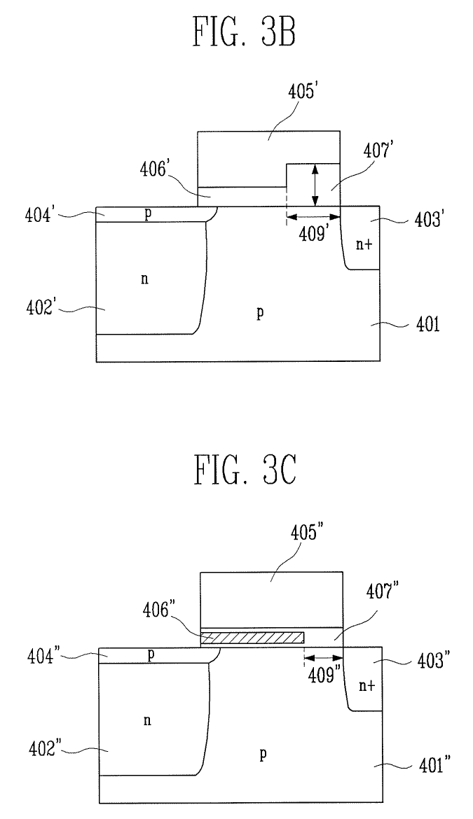

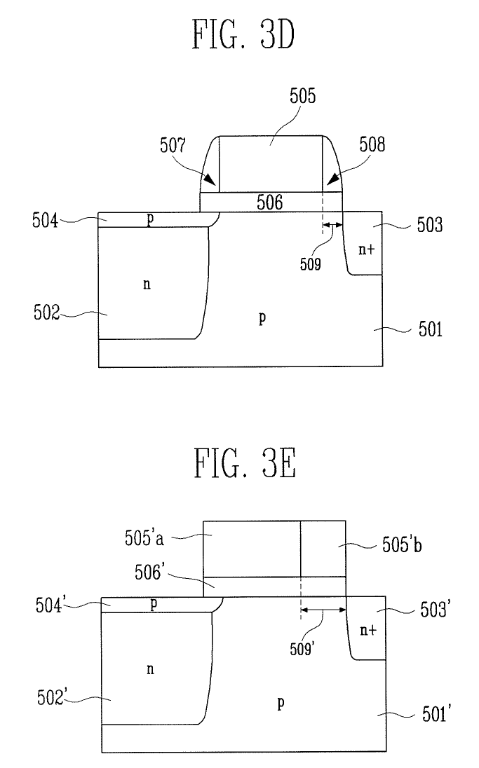

The transfer transistor of FIG. 3a includes a gate electrode 405, (Tate insulating layers 406 and 407, and a substrate 401, and a photodiode region includes a photodiode doping region 402, and a surface doping region 404. This structure is characterized in that a depletion region 409 that is insignificantly influenced by a gate turn-on voltage is formed by a gate insulating layer of a transfer transistor having irregular thickness. The depletion region acts to separate a channel of the transfer transistor and the diffusion node 403 using the depletion region. The gate insulating layer 407 adjacent to the diffusion node side is thicker so that the gate turn-on voltage does not have an effect on the diffusion node 403.

A method of fabricating a gate insulating layer having irregular thickness includes: a method in which an insulating layer growth suppression material such as nitrogen implantation is partially used when the gate insulating layer is formed; a method in which an implantation concentration of a side adjacent to the photodiode is different from that of a side adjacent to the diffusion node so that the thickness of the gate insulating layer is adjusted; and a method in which an insulating layer is partially etched and reformed using a mask after a gate insulating layer is formed on a substrate to adjust the thickness. A structure of insulating layers 406′ and 407′ having thicknesses of two or more steps as illustrated in FIG. 3b, or a structure of insulating layers 406 and 407 having a thickness getting gradually thicker as illustrated in FIG. 3a may be applied.

The structure in which a part of the insulating layer 407 adjacent to the diffusion node is relatively thicker as illustrated in FIG. 3a makes the breakdown voltage of the diffusion node side of the transfer transistor higher than the voltage obtained by subtraction of the operating gate voltage applied to the transfer transistor from the voltage of the diffusion node.

In other words, according to the structure of the insulating layer having the illustrated irregular thickness, when it is assumed that the transfer transistor gate corresponds to a general gate, and the diffusion node 403 corresponds to a source in the typical MOS structure, even though the turn-on voltage of the transfer transistor is applied, the voltage does not exceed the breakdown voltage, so that electrons are not transferred to a gate channel.

Since an area corresponding to a thick region 407 in the insulating layer of the transfer transistor is a region where the channel of the transfer transistor is not formed, channel capacity of the transfer transistor is reduced. Therefore, the thick region may be formed on the diffusion node side with a minimum size within a range where a charge is not transferred to the channel of the transfer transistor in the diffusion node region according to edge effects of a thin region 406.

Even in the case where the gate insulating layer of the transfer transistor includes two or more materials having different dielectric constants, when the diffusion node side has a thicker gate insulating layer than a photodiode side based on the thickness converted by a silicon oxide layer into equivalent oxide thickness (EOT), the structure according to the aspect of the present invention may be implemented. In this case, a material 407″ having a low dielectric constant and a material 406″ having a high dielectric constant are partially used as illustrated in FIG. 3c or, while it is not shown, a ratio of the material having a high dielectric constant to that of the material having a low dielectric constant in the total thickness of the gate insulating layer is different from each other so that the gate insulation layers 406″ and 407″, the diffusion node side of which is thicker based on the EOT, are formed even though the gate insulating layers have physically the same thickness.

A light sensing pixel of FIG. 3d is disposed between a diffusion node region and a channel region of a transfer transistor, and includes a gap region 509 on which a gate electrode of the transfer transistor does not exist.

The illustrated transfer transistor includes a gate electrode 505, a gate insulating layer 506, spacers 507 and 508, and a substrate 501. Also, a photodiode region includes a photodiode doping region 502 and a surface doping region 504. The gate electrode 505 of the transfer transistor is separated from the diffusion node 503 by the spacer 508 so that a gap region 509 is formed in a channel region below the spacer 508. The gap region 509 acts to separate the channel of the transfer transistor from the diffusion node 503 by a depletion region. In other words, even though a turn-on voltage is applied to a gate of the transfer transistor, since the gate electrode 505 is separated from the diffusion node 503, a charge in the diffusion node is not emitted into the channel of the transfer transistor.

After the gate insulating layer 506 is formed and the gate electrode 505 is defined, ion implantation for source and drain extension between the gate electrode 505 and the diffusion node 503 is not performed. Instead, the spacer 508 is formed, and ion implantation of n-type impurities for forming the diffusion node 503 is separately performed. At this time, the gate electrode is defined and the thickness of the spacer 508 is adjusted so that the size of the gap region 509 by which the gate electrode 505 is separated from the diffusion node 503 may be adjusted.

It is apparent that the size of the gap region 509 should be appropriately adjusted so that the charge in the channel of the transfer transistor can be easily transferred to the diffusion node 503 when the photodiode is reset and transferred, the lateral electric field according to the diffusion node 503 has an effect on the channel, and the charge in the diffusion node 503 is not emitted to the channel of the transfer transistor according to edge effects of the gate electrode 505.

Another method of forming the gap region without using the spacer of the transfer transistor includes a method in which the gate electrode of the transfer transistor is separated from the diffusion node using a separate photomask.

Under a specific operating voltage, a depletion region between a channel of a transfer transistor and a diffusion node may be formed by partially adjusting a work function of a gate electrode material. As illustrated in FIG. 3e, when the channel formation region of the transfer transistor is doped with p-type impurities and the diffusion node is doped with n-type impurities, heavily doped n-type polysilicon is generally used for the gate electrode material. As illustrated, when a work function of the gate electrode material 505′b adjacent to the diffusion node is higher than that of the gate electrode material 505′a adjacent to the photodiode, a breakdown voltage of the diffusion node is increased by a difference of the work function of a substrate 501′ and the work function of the gate electrode material 505′b. This same process can be used to increase the channel doping concentration and the thickness of the gate insulating layer.

For example, in a structure of FIG. 3e, when 505′a is heavily doped n-type polysilicon and 505′b is heavily doped p-type polysilicon, a difference in work function between the gate electrode materials is about IV or higher. Therefore, the breakdown voltage of a substrate region corresponding to the channel formation region 509′ below 505′b is increased by about IV or higher than a substrate region corresponding to the channel formation region below 505′a.

The work function difference between the gate electrode materials should be a value or greater at which a channel is not formed below a transfer transistor adjacent to a diffusion node under a specific transfer gate operating voltage, so that the channel region is separated from the diffusion node. When the electrode materials doped with impurities are used as the gate electrode material that can be used for the above structure, different doping concentrations may be used so that work function difference can be obtained. Also, when the electrode material consists of two or more materials, different mole fractions of the materials that constitute the electrode material are used so that desired work function difference can be obtained. In addition, basic electrode materials for constituting each of the two gate electrodes 505′a and 505′b identified in FIG. 3e may be differently used so that desired work function difference can be obtained.

In FIGS. 3a to 3e, the impurity concentration of substrate regions corresponding to the depletion regions 409, 409′, 409″, 509, and 509′ may be the same as that of the substrate, or the same as the impurity concentration of a substrate region corresponding to the channel formation region of the transfer transistor.

### Third Exemplary Embodiment

A light sensing pixel of the present exemplary embodiment has a potential barrier adjustment structure in which a potential barrier, when a charge of a photodiode is transferred to a channel of a transfer transistor, is maintained at the same level.

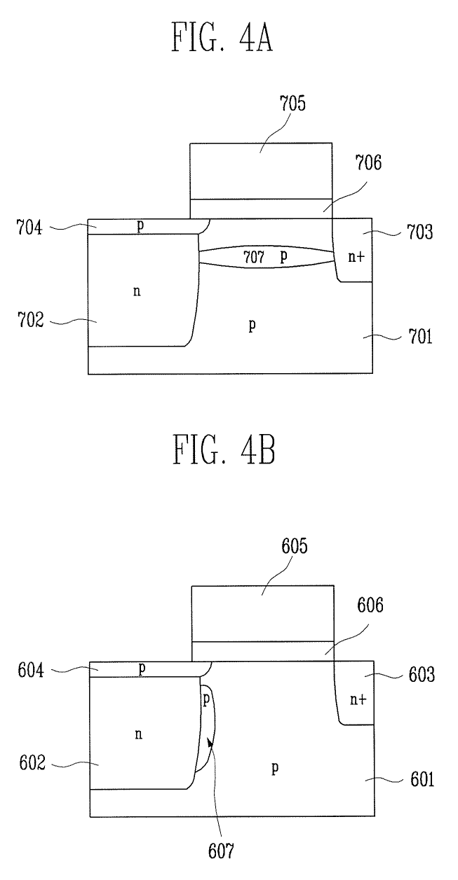

When the photodiode is reset or transferred, a potential barrier exists between the photodiode and the channel of the transfer transistor. Actually, the magnitude of the potential barrier sensed by the charge that is transferred from the photodiode to the transfer transistor varies depending on a turn-on voltage of the transfer transistor and a method of applying the voltage, the magnitude of coupling capacity between the transfer transistor and a diffusion node, the amount of equilibrium channel charge when the transfer transistor is turned on, the amount of charge corresponding to the well capacity of the photodiode, the amount of charge emitted to the channel of the transfer transistor from the diffusion node, etc. The exemplary embodiments of structures for preventing the change in the potential barrier according to the depletion of the channel of the transfer transistor, and the change in the voltage of the diffusion node are as illustrated in FIGS. 4a and 4b.

A light sensing pixel illustrated in FIG. 4a includes a potential adjustment doping region 607 that is disposed at a side of an internal doping region 602 of the photodiode adjacent to a substrate of the transfer transistor and is more heavily doped with the same type as the substrate of the transfer transistor.

The transfer transistor of FIG. 4a includes a gate electrode 605, a gate insulating layer 606, and a substrate 601. Also, a photodiode region includes a photodiode internal doping region 602, and a surface doping region 604. The potential adjustment doping region 607 is a region formed at a side adjacent to the transfer transistor of the photodiode, and doped with the same doping material as the substrate 601. The potential adjustment doping region 607 has a higher doping concentration than the substrate and a concentration lower than or equal to the surface doping region 604.

The potential adjustment doping region 607 is separated from the surface doping region 604, and acts to maintain the potential barrier sensed by the charge of the photodiode when it is transferred to a channel of the transfer transistor according to depletion of the channel of the transfer transistor or the change in the voltage of the diffusion node 603 at the same level. When the charge is not emitted from the diffusion node 603 to the channel of the transfer transistor, after the transfer transistor is reset and transferred at a specific gate turn-on voltage, the same amount of charge is left in the photodiode.

A light sensing pixel of FIG. 4b includes a potential adjustment doping region 707 parallel to a channel of a transfer transistor rather than a side of a photodiode and doped with the same doping material as a substrate 701 in order to reduce the change in the potential barrier between the photodiode and the channel of the transfer transistor.

The potential adjustment doping region 707 has a doping concentration higher than that of the substrate, and a doping concentration lower than or equal to that of a surface doping region 704. Also, the potential adjustment doping region 707 may be separated from the surface doping region 704. The potential adjustment doping region 707 acts to maintain the potential barrier caused when the photodiode is reset or transferred at the same level so that the illustrated light sensing pixel can be more efficiently reset and transferred at a specific turn-on voltage of the transfer transistor regardless of the voltage of the diffusion node 703.

An image sensor of the present invention having the above structure is capable of efficiently reducing dark current, fixed pattern noise, clock-feed-through in a channel, etc., even in a low operating voltage environment.

Also, in the present invention, a fully depleted photodiode or a partially depleted photodiode is not sensitive to process variables. Further, the reset and transfer of the photodiode are constantly performed regardless of the operating voltage, a method of applying the voltage, etc., thereby facilitating the process and driving method.

In addition, since the present invention may be implemented based on the process being used, it can be seen as an improvement on the conventional art.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A light sensing pixel, comprising:
a photodiode for generating a light-induced charge generated by light;
a transfer transistor for transferring the light-induced charge to a diffusion node; and
a depletion-induced structure for separating a channel region of the transfer transistor and the diffusion node region by a depletion region regardless of the magnitude of an operating voltage applied to the transfer transistor.

2. The light sensing pixel of claim 1, wherein the depletion-induced structure is disposed between the diffusion node region and the channel region of the transfer transistor, and is formed of a depletion-induced doping portion doped with a doping type opposite to that of the diffusion node region.

3. The light sensing pixel of claim 2, wherein the depletion-induced doping portion is in the shape of a pocket or a halo.

4. The light sensing pixel of claim 2, wherein the depletion-induced doping portion is formed between the diffusion node and the channel of the transfer transistor by ion implantation of impurities.

5. The light sensing pixel of claim 1, wherein the depletion-induced structure comprises:
a first depletion-induced doping portion disposed between the diffusion node region and the channel region of the transfer transistor, and doped with the same doping type as that of the diffusion node region; and
a second depletion-induced doping portion disposed between the channel region of the transfer transistor and the first depletion-induced doping portion, and doped with a doping type opposite to that of the diffusion node region.

6. The Tight sensing pixel of claim 5, wherein the first and second depletion-induced doping portions are in the shape of a pocket or a halo.

7. The light sensing pixel of claim 5, wherein the first and second depletion-induced doping portions are formed between the diffusion node region and the channel of the transfer transistor by ion implantation of impurities.

8. The light sensing pixel of claim 1, wherein the depletion-induced structure is disposed between the diffusion node region and the channel region of the transfer transistor, and is formed of a depletion region caused by a gate insulating layer of the transfer transistor using irregular thickness of the gate insulating layer based on equivalent oxide thickness (EOT).

9. The light sensing pixel of claim 8, wherein the gate insulating layer of the transfer transistor has a thickness gradually increased from a part adjacent to the photodiode toward the diffusion node.

10. The light sensing pixel of claim 8, wherein the gate insulating layer of the transfer transistor has a discontinuous thickness of two or more steps.

11. The light sensing pixel of claim 8, wherein the gate insulating layer of the transfer transistor uses and adjusts impurities consisting of two or more insulating materials or having an effect on a dielectric constant of the insulating layer so that a floating diffusion node side is thicker than the photodiode side based on the EOT.

12. The light sensing pixel of claim 8, wherein the gate insulating layer of the transfer transistor is formed by a method of partial etching and insulating layer reformation.

13. The light sensing pixel of claim 8, wherein the gate insulating layer of the transfer transistor is formed by partially using an insulating layer growth suppression material or an insulating layer growth acceleration material.

14. The light sensing pixel of claim 8, wherein in the gate insulating layer of the transfer transistor, a part adjacent to the photodiode is different in implantation concentration of insulating layer growth suppression or growth acceleration doping material from that of a part adjacent to the diffusion node.

15. The light sensing pixel of claim 1, wherein the depletion-induced structure is disposed between the diffusion node region and the channel region of the transfer transistor, and its upper part has a gap region where a gate electrode of the transfer transistor does not exist.

16. The light sensing pixel of claim 15, wherein the gap region is formed by a spacer adjacent to the gate electrode of the transfer transistor.

17. The light sensing pixel of claim 15, wherein the gap region is formed by performing separate ion implantation for forming the diffusion node after forming the spacer on the gate electrode instead of performing ion implantation for source and drain extension after the gate insulating layer and the gate electrode material of the transfer transistor are formed and defined.

18. The light sensing pixel of claim 15, wherein the gap region is formed by separating the gate electrode of the transfer transistor from the diffusion node using a separate photomask rather than the spacer of the transfer transistor.

19. The light sensing pixel of claim 1, wherein the depletion-induced structure is formed of a gate electrode in which a work function of a material of a part adjacent to the photodiode is different from that of a material of a part adjacent to the diffusion node.

20. The light sensing pixel of claim 19, wherein the gate electrode material is an electrode material formed of a single compound such as polysilicon or a single material that is doped with impurities, and has different concentrations of impurities to be doped to thereby have a work function difference.

21. The light sensing pixel of claim 19, wherein the gate electrode material is an electrode material using a single compound such as the polysilicon or a single material that is doped with impurities, and has different types of impurities to be doped to thereby have a work function difference.

22. The light sensing pixel of claim 19, wherein the gate electrode material is an electrode material consisting of two or more materials, for example, SiₓGe₁₋, Ti/TiN, Al/TiN, and TaSiN, and has a desired work function difference by varying mole fractions of the materials constituting the electrode material.

23. The light sensing pixel of claim 19, wherein, in the electrode material, a basic electrode material of the part adjacent to the photodiode is different from that of the part adjacent to the diffusion node.

24. A light sensing pixel, comprising:
a photodiode for generating a light-induced charge generated by light;
a transfer transistor for transferring the light-induced charge to the diffusion node; and
a potential adjustment structure for maintaining a potential barrier when the charge of the photodiode is transferred to a channel of the transfer transistor at the same level.

25. The light sensing pixel of claim 24, wherein the potential adjustment structure is formed at a side of an internal doping region of the photodiode adjacent to a substrate of the transfer transistor, and is a more heavily doped region of the same type as the substrate of the transfer transistor.

26. The light sensing pixel of claim 24, wherein the potential adjustment structure is formed below the channel of the transfer transistor in parallel to the channel, and is a more heavily doped region of the same type as the substrate of the transfer transistor.
